(19) United States
(12) Patent Application Publication
(10) Pub. No.: US 2010/0215193 A1
(43) Pub. Date: Aug. 26, 2010

(54) Speaker Distortion Deduction System and Method

(75) Inventors: James Walter Wihardja, Fullerton, CA (US); Harry K. Lau, Norwalk, CA (US); Trausti Thormundsson, Irvine, CA (US); Yair Kerner, Kiryat Ono (IL)

Correspondence Address: CONEXANT SYSTEMS, INC, LEGAL DEPARTMENT - ATTN: LUCY COONEY, 4000 MacArthur Blvd., Mail Stop E01-339, Newport Beach, CA, 92660, US

(73) Assignee: CONEXANT SYSTEMS, INC., Newport Beach, CA (US)

(21) Appl. No.: 12/712,108

(22) Filed: Feb. 24, 2010

Related U.S. Application Data
(60) Provisional application No. 61/155,397, filed on Feb. 25, 2009.

(51) Int. Cl. H03G 5/00

(52) U.S. Cl. 381/103

(57) ABSTRACT

Many speakers, especially small speakers are susceptible to distortion if too much power is applied in certain vulnerable frequency bands. The distortion can be prevented by applying equalization to the audio signal driving the speaker. An equalizer can be configured to suppress the audio signal in the vulnerable frequency bands. The equalizer monitors the power in the vulnerable frequency bands and suppresses those vulnerable frequency bands only when they have sufficient power to distort. In this fashion, undesired audio effects due to the equalization can be avoided.

### RELATED APPLICATIONS

This application claims priority under 35 U.S.C. §119 to U.S. Patent Application No. 61/155,397 filed Feb. 25, 2009, entitled “Speaker Distortion Reduction Systems and Methods.”

### BACKGROUND OF THE INVENTION

1. Field of the Invention

The invention relates in general to audio playback systems and specifically to reducing distortion caused by speakers.

2. Background Information

Small speakers have found prolific uses in the state of the art. They appear in computers, particularly laptops, but also exist in telephones, in particular cordless and cellular phones. Additional applications include MP3 players and video cameras. Generally for these applications, the small speakers do not have the dynamic ranges and linear frequency responses of their larger or more expensive counterparts. As a result, many small speakers are susceptible to intense distortion if power delivered in certain frequency bands become too strong.

In some applications, it is desirable to reduce distortion in a speaker. One approach is to maintain the power levels of these vulnerable frequency bands below the distortion power threshold. For the purposes of this disclosure, the distortion power threshold for a given frequency band is the amount of power in the given frequency band the speaker can tolerate before the distortion becomes unacceptable for a particular audio application. A speaker's vulnerable frequency bands are frequency bands that have particularly low distortion power thresholds that may be exceeded during speaker use.

In the present day, a trend has been moving more towards purchasing music via download rather than through a compact disc. Additionally, users are increasingly using devices such as computers, phones, MP3 players, and even combination video cameras as a means for listening to music. All of these use the small speakers mentioned. When a user listens to music, he may be forced to turn down the volume when the music causes a vulnerable frequency band to reach its distortion power threshold.

Some playback applications may allow the user to apply an equalizer during the playback. Depicted in FIG. 1 is a typical interface for an equalizer. The user is provided with sliders 102, 104, 106, 108, and 110. Each slider controls the attenuation or gain of a frequency range usually depicted by a center frequency shown by labels 112, 114, 116, 118 and 120. Typically, the equalizers comprise a collection of band pass filters centered at a center frequency. The sliders allow the user to adjust the attenuation provided by the band pass filter.

It should be noted that gain and attenuation are mentioned together. Gain or attenuation is applied to a signal to relatively suppress a portion of an audio signal. If the power level is actually reduced the signal is attenuated. If the power level is increased but not compared to other frequency bands, gain is applied, but relatively speaking the portion of the audio signal is actually suppressed. For the purposes of this disclosure, the terms applying gain or attenuation may be used interchangeable, but should be understood to mean a scaling of a portion of the audio signal relative to the rest of the audio signal.

While providing the end user an equalizer allows the user to tune the output to avoid distortion without necessarily turning down the overall volume, this approach has significant shortcomings. First, the bandwidth of the filter controlled by each slider is often too broad so attenuating the vulnerable frequency band has a significant impact on other frequencies negatively impacting the quality of the playback. Second, due to the nature of music, every song or composition has a different frequency profile. A given song may require attenuation to prevent a vulnerable frequency band from exceeding the distortion power threshold while a second song may not, so either the user has to readjust the equalizer or the second song is unnecessarily altered.

Another approach is to provide a preconfigured equalizer. The preconfigured equalizer can attenuate frequencies using band pass filters covering known vulnerable frequency bands. This approach has the advantage of exploiting the knowledge of the particular frequency bands that are vulnerable. Additionally, the bandwidth of the constituent band pass filters can be narrower than that of the user adjusted equalizer, thus minimizing the impact on other frequencies. However, this approach still has the shortcoming that depending on the song played a band pass filter may be unnecessarily applied to the song thus introducing undesired playback effects when not necessary. Accordingly, various needs exist in the industry to address the aforementioned deficiencies and inadequacies.

### SUMMARY OF INVENTION

A system for reducing distortion in a speaker comprises an equalizer or equalizer module which can attenuate or suppress the vulnerable frequency bands of the speaker in an audio signal. A monitoring module measures the signal intensity for each of the vulnerable frequency bands and supplies the intensity levels to the control module which is configured to adjust the suppression or attenuation if any the equalizer applies to each vulnerable frequency band. This adjustment is made so that the resultant power remaining in the vulnerable frequency band is not sufficient to cause significant distortion in the speaker. For a given speaker the intensity level in each vulnerable frequency band sufficient to cause distortion is determined and this intensity level is referred to as the distortion power threshold. The control module receives measured signal intensities from the monitoring module and controls the equalizer to suppress the audio signal so that the intensity level in the vulnerable frequency band is lower than the intensity level sufficient to cause distortion. Additionally, the monitoring module can measure the signal before equalization or after equalization in a feedback configuration.

The system can also be pre-emptive by delaying the audio signal prior to equalization, so that a large spike in the intensity in a vulnerable frequency band can be predicted and a transition to the attenuation can be applied to avoid an abrupt transition that may produce undesirable playback artifacts.

The monitoring module can comprise a band pass filter and a module that measures the root mean square (RMS) power for each vulnerable frequency band. This band pass filter can be centered at the center frequency of the vulnerable frequency band and have a bandwidth greater than or equal to the band width of the vulnerable frequency band. The equalizer can comprise one or more band equalizers. Each band equalizer can also be centered at the center frequency of the vulnerable frequency band and have a bandwidth greater than or equal to the band width of the vulnerable frequency band.

The system can also account for an attack and release time when transitioning to and from attenuation a vulnerable frequency band. The attenuation can also account for the master volume set by the user.

The system can also be applied to a multi channel playback system such as stereo or surround sound. At the option of the user or based on a preset configuration, the attenuation applied to each channel can be locked so that the effect on each channel by the equalizer is uniform.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF DRAWINGS

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 depicts a typical user interface for an equalizer as known in the prior art;

FIG. 2A illustrates a playback system in accordance with an embodiment of the invention;

FIG. 2B illustrates an alternative playback system in accordance with an embodiment of the invention;

FIG. 2C illustrates an alternate playback system in accordance with an embodiment of the invention;

FIG. 3 illustrates an embodiment of a speaker distortion reduction module;

FIG. 4 illustrates an embodiment of a speaker distortion reduction module including predictive speaker distortion reduction;

FIG. 5 illustrates an embodiment of a speaker distortion reduction module employing filtering in the frequency domain;

FIG. 6 illustrates a frequency domain speaker distortion reduction module in accordance with an embodiment;

FIG. 7 illustrates an embodiment of a time domain speaker distortion reduction module;

FIG. 8 illustrates an exemplary embodiment of a frequency band limiter stage;

FIG. 9 illustrates an embodiment of a multi-channel audio playback system; and

FIG. 10 illustrates an embodiment of a speaker distortion reduction system.

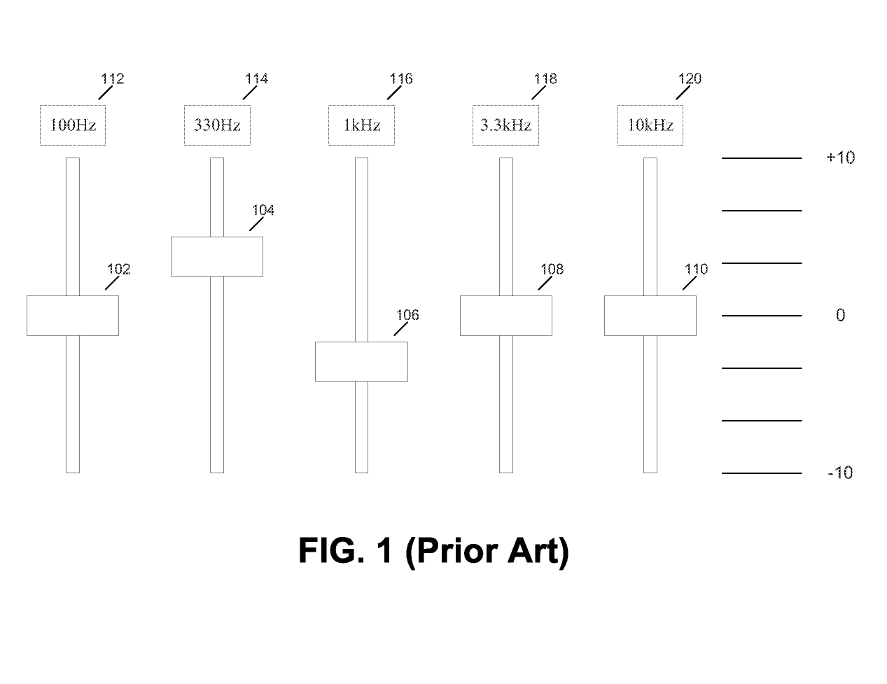

### DETAILED DESCRIPTION

A detailed description of embodiments of the present invention is presented below. While the disclosure will be described in connection with these drawings, there is no intent to limit it to the embodiment or embodiments disclosed herein. On the contrary, the intent is to cover all alternatives, modifications and equivalents included within the spirit and scope of the disclosure as defined by the appended claims.

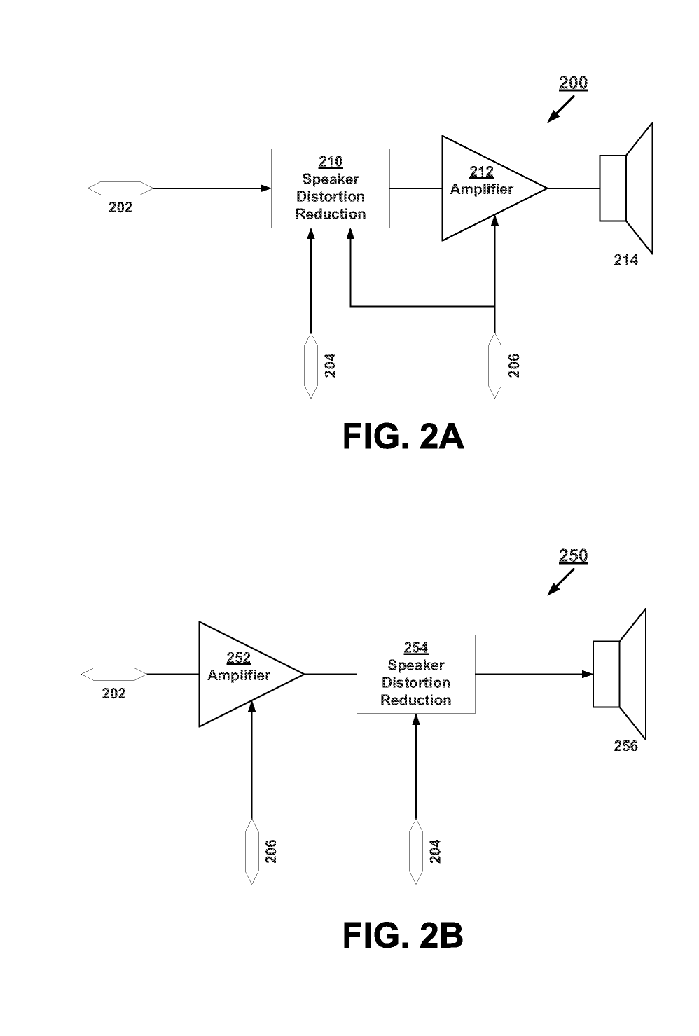

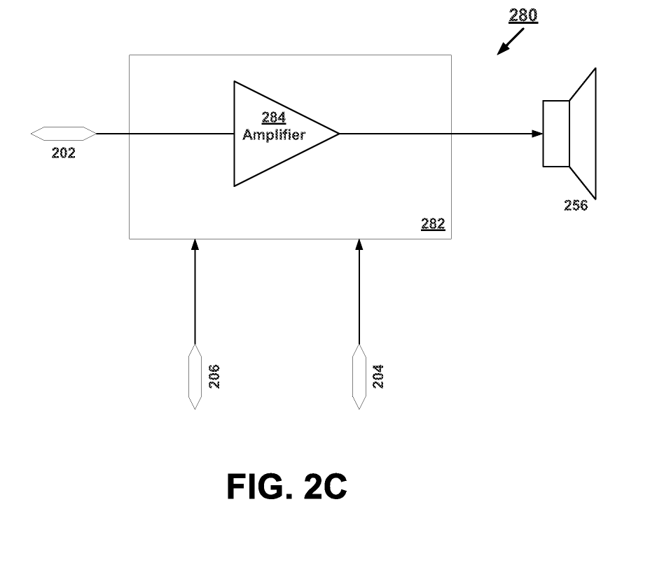

FIG. 2A illustrates an embodiment of a playback system. Audio signal 202 is received by speaker distortion reduction module 210 which receives speaker distortion reduction parameters 204 and user volume information 206. Speaker distortion reduction module filters audio signal 202 which is then amplified by amplifier 212 under the control of user volume information 206. The resultant amplified audio signal can be played back on speaker 214. Speaker distortion reduction parameters 204 comprise information used to reduce potential distortion at speaker 214. In one embodiment the speaker distortion parameters 204 include a vulnerable frequency band specified as a center frequency and a bandwidth, and the corresponding distortion power threshold for the speaker 214. Other examples of speaker distortion reduction parameters are given below in more detail. User volume information 206 is information supplied by the end user (e.g., through volume controls on a music player) to indicate the desired volume of the audio system. Speaker distortion reduction module 210 filters the audio to produce a signal for the speaker 214 that avoids distortion. A more specific description of the manner in which the filtering occurs is given below.

FIG. 2B illustrates an alternative embodiment of a playback system incorporating. System 250 differs from system 200 in that the speaker distortion reduction module and the amplifier are reversed in location. Audio signal 202 is received and amplified by amplifier 252 based on user volume information 206. Speaker distortion reduction module 254 filters the amplified audio signal using speaker distortion reduction parameters 204. The resultant filtered signal is played back on speaker 256. In this embodiment, speaker distortion reduction module 254 does not require user volume information 206. Speaker distortion reduction module 254 filters a fully amplified signal from amplifier 252.

FIG. 2C illustrates another embodiment of a playback system. System 280 integrates amplifier 284 into speaker distortion reduction module 282. The speaker distortion reduction parameters 204 and user volume information 206 are supplied to speaker distortion reduction module 282 which selectively applies gain to input signal 202 based on the power levels of the vulnerable frequency band. For example, the speaker distortion reduction module 282 may be configured to such that the vulnerable frequency band of input signal 202 is not amplified.

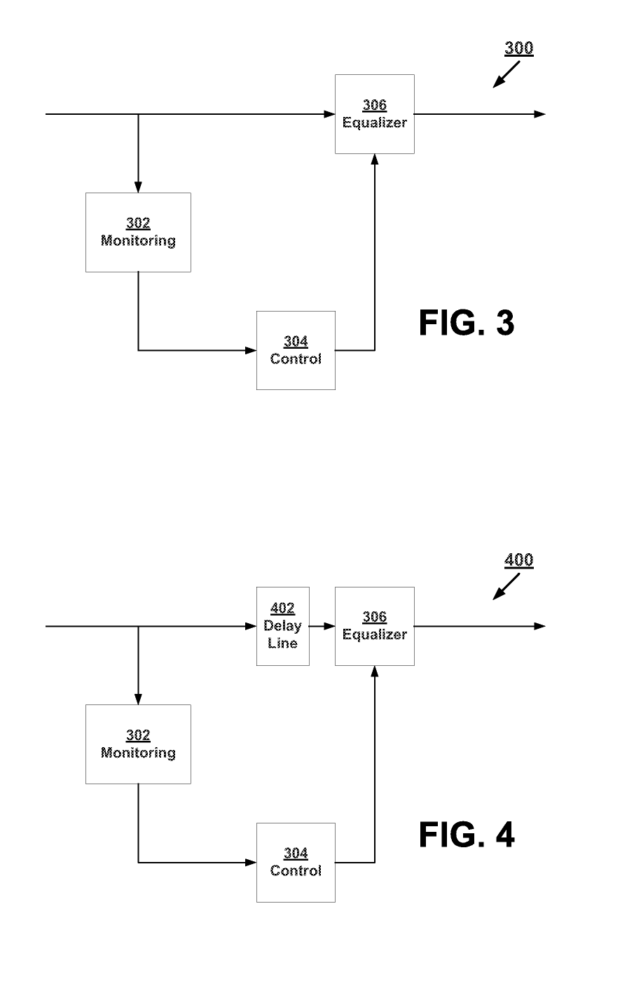

FIG. 3 illustrates an embodiment of a speaker distortion reduction module. This module can be used in system 200 and system 250. Speaker distortion module 300 comprises monitoring module 302 which monitors vulnerable frequency bands. The result of the monitoring is provided to control module 304 which determines whether any attenuation or gain is to be provided to equalizer 306. The vulnerable frequency bands can be predetermined if there is knowledge of the particular type of speaker used or can be programmed at a later time when the particular type of speaker is known.

In particular, control module 304 receives information about the vulnerable frequency bands from monitoring module 302. In one embodiment, the received information includes the root mean square (RMS) power levels of each of the vulnerable frequency bands. If the power level of a vulnerable frequency band exceeds the corresponding distortion power threshold for that band, then control module 304 adjusts equalizer 306 so that the vulnerable frequency band is suppressed. Rather than completely suppressing the vulnerable frequency band, the vulnerable frequency band need only be attenuated until the vulnerable frequency band in the resultant filtered signal is below the distortion power threshold. In an alternate embodiment, the distortion power threshold is an absolute distortion power threshold which does not change based on user volume information (such as system 250) or it can be relative based on the user volume information. For example, if the user turns up the volume, the relative distortion power threshold should be lowered so when the audio signal is amplified, the resultant signal will stay below the distortion power threshold of the speaker.

The information provided by monitoring module 302 can be reactive or predictive. If equalizer 306 adjusted in response to the immediate power levels of the vulnerable frequency bands, the information is reactive. However, if equalizer 306 is adjusted in response to the predicted or future power levels of the vulnerable frequency bands, the information is predictive.

FIG. 4 illustrates a speaker distortion reduction module which incorporates predictive speaker distortion reduction. Monitoring module 302, control module 304 and equalizer 306 function in a similar fashion as described for FIG. 3. However, an additional component, delay line 402, is included. Delay line 402 delays the audio signal for a predetermined period. Since the audio playback is then shifted by this predetermined period, equalizer 306 can be adjusted in anticipation of the power levels at the vulnerable frequency bands. By employing the delay line, even brief speaker distortions can be eliminated.

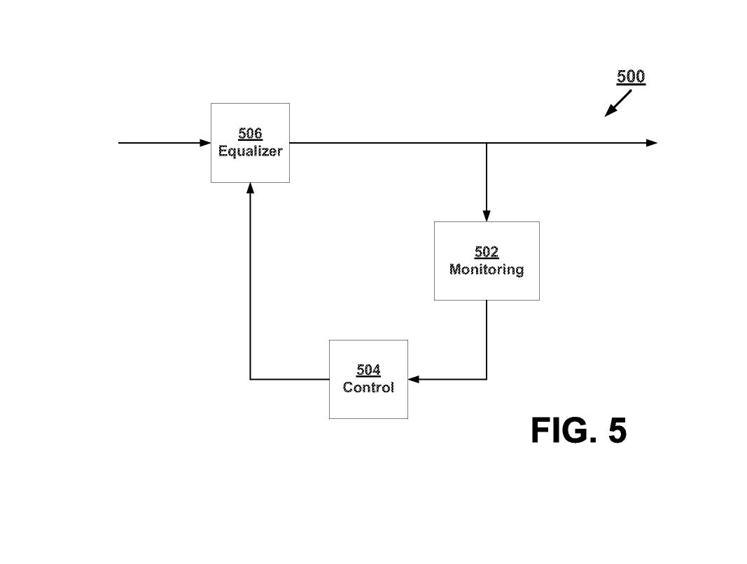

FIG. 5 illustrates another embodiment of the speaker distortion reduction system. Rather than monitor the audio signal before equalizer 506, monitoring module 502 monitors the audio signal after equalizer 506, thus configuring control module 504 to operate in a feedback loop. Equalizer 506 functions similarly to equalizer 306 and can operate in the time-domain or frequency domain as described above. Equalizer 506 can also comprise one or more band equalizers as described above. Monitoring module 502 functions similarly to monitoring module 302. Control module 504 function similarly to control module 506. Optionally, a delay line can also be employed.

The audio signal described above can be an analog signal and analog components can be used for monitoring module 302, control module 304, and equalizer 306. The audio signal can also be a digital signal and likewise digital components can be used. A mixture of digital and analog components can also be used. Although depicted as hardware modules, individual modules can also be implemented either in hardware, software, firmware or combination thereof. In addition the audio signal can be processed in the time domain or frequency domain.

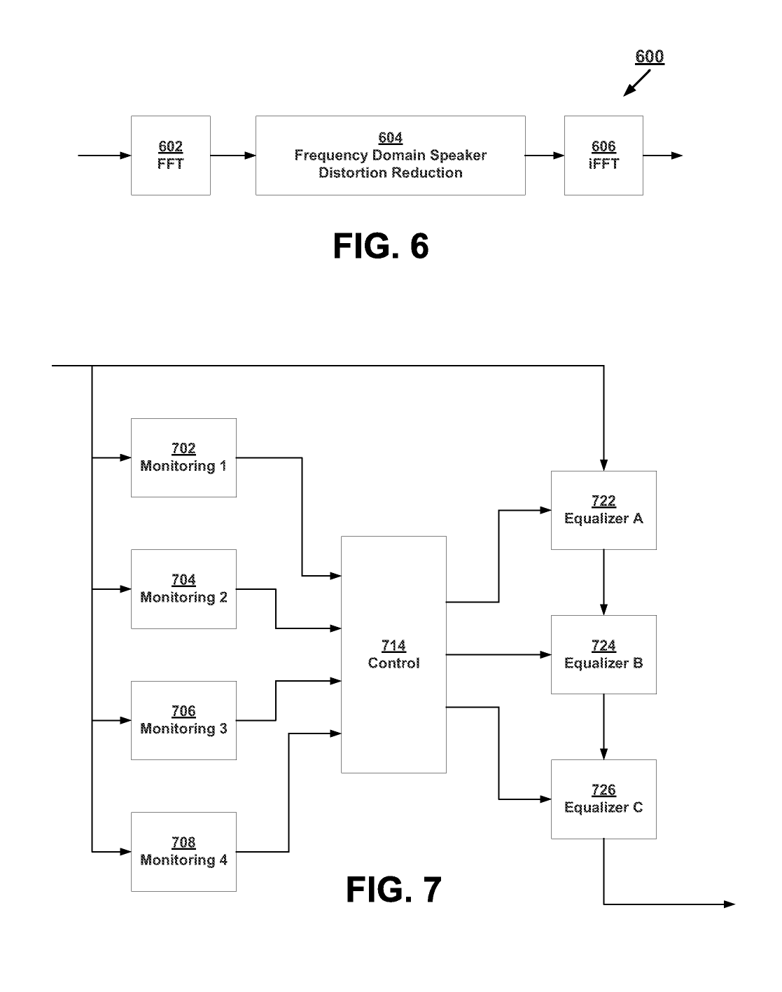

FIG. 6 illustrates an embodiment of a speaker distortion reduction module employing filtering in the frequency domain. A time-domain audio signal is converted to the frequency domain using fast-Fourier transform (FFT) 602. The resultant frequency domain signal is examined by frequency domain speaker reduction module 604 for the power levels at the vulnerable frequency bands, if the power level at the vulnerable frequency band exceeds the distortion power threshold, the vulnerable frequency band can be suppressed sufficiently so as the distortion power threshold is not exceeded. Because the audio signal is in the frequency domain, a clipping function can be applied that clips the audio signal whenever frequencies within a vulnerable frequency band exceed its distortion power threshold. The filtered signal is then returned to the time domain using inverse FFT (iFFT) 606. The use of FFTs and iFFT on the audio signal may employ windows, segmentation and reassembly to facilitate the frequency domain processing.

FIG. 7 illustrates another embodiment of a frequency domain speaker distortion reduction module. A plurality of monitoring modules (depicted as modules 702, 704, 706, and 708) are tuned to a plurality of vulnerable frequency bands, respectively. The power levels of each of the vulnerable frequency bands are supplied to control module 714. Control module 714 receives the power levels and other parameters similar to those described above and below, and directs a plurality of equalizers (depicted as equalizer 722, 724 and 726) to selectively suppress a plurality of frequency bands. These equalizers need not correspond in a one to one fashion with the monitoring modules. For example, in some of the psychoacoustic masking techniques described below, masking frequencies may be monitored by the monitoring modules, but their power levels do not directly control an equalizer, so not all monitoring modules are associated with an equalizer.

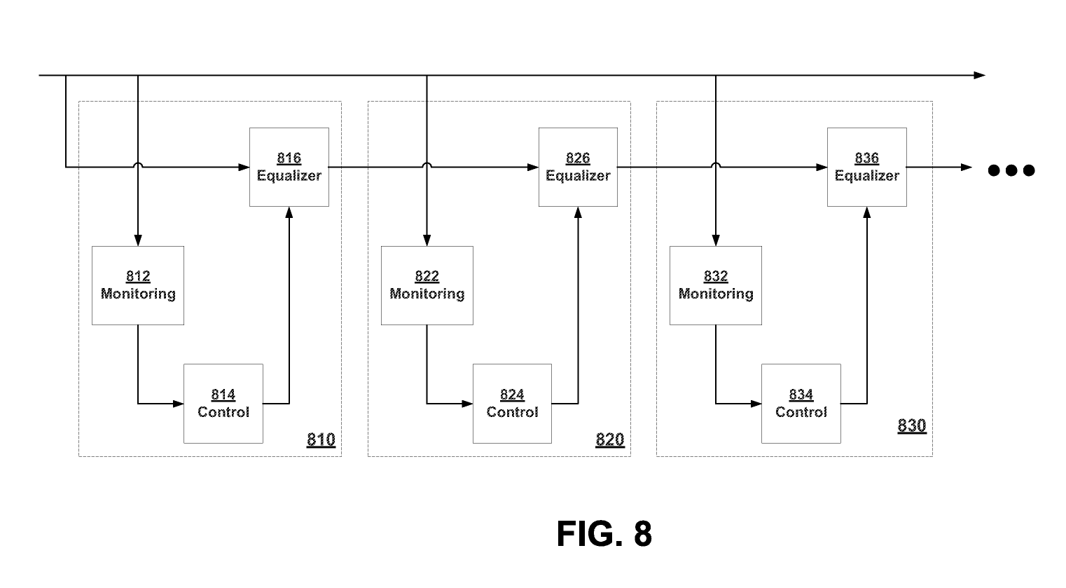

FIG. 8 illustrates an embodiment of a time domain speaker distortion reduction module. In this example, rather than using a single equalizer, each vulnerable frequency band is addressed individually by stage. It comprises a plurality of frequency band limiter stages each designed to restrain a given vulnerable frequency band from exceeding its distortion power threshold. The figure depicts three frequency band limiter stages 810, 820, and 830 of potentially many frequencies within speaker distortion reduction module 800. Within each frequency band limiter is a monitoring module (e.g., monitoring module 812 within frequency band limiter stage 810), a control module (e.g., control module 814 within frequency band limiter stage 810), and a band equalizer (e.g., equalizer 816 within frequency band limiter stage 810). The monitoring module is responsible for monitoring the signal at the given vulnerable frequency band for the frequency band limiter stage. The resulting information is provided to the corresponding control module which determines the gain or attenuation needed for the given vulnerable frequency. Finally, the gain or attenuation is provided to the band equalizer which can suppress the signal at the given vulnerable frequency band. A different frequency band limiter stage would be assigned a different vulnerable frequency band to monitor and potentially suppress. As many frequency band limiter stages can be linked serially as needed to account for each vulnerable frequency bands.

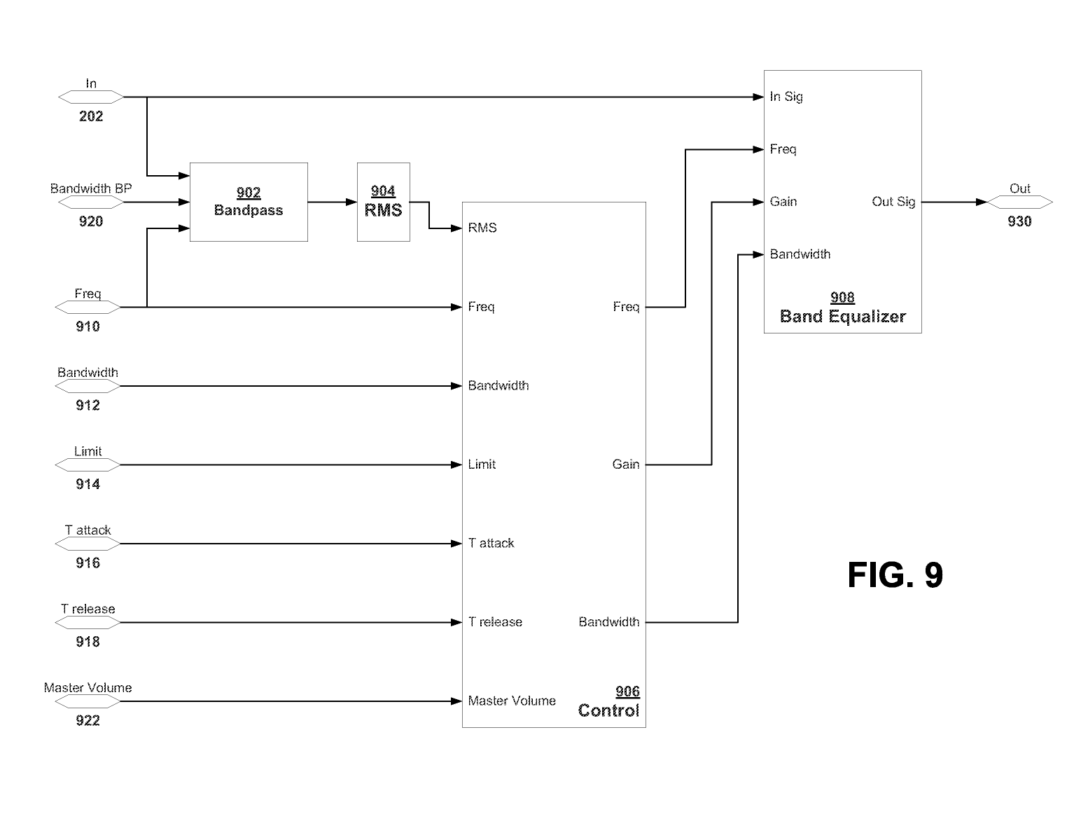

FIG. 9 illustrates an exemplary embodiment of a frequency band limiter stage. The monitoring module comprises band pass filter 902 and RMS module 904. The band pass filter is configured to select a band covering the vulnerable frequency band of interest. The RMS module determines the RMS power of the filtered signal which should be approximately the RMS power of the audio signal in the vulnerable frequency band. Based on a variety of parameters, control module 906 determines the attenuation or gain needed to suppress any potentially speaker distorting component of the audio signal residing in the vulnerable frequency band. This gain or attenuation is provided to band equalizer 908 which attenuates the vulnerable frequency band. Frequency band limiter stage 800 is designed to be fully programmable and has many parameters available. It should be understood that not all parameters are required and that any of these parameters could be preset and hardcoded to fix values.

Frequency parameter 910 is provided to both band pass filter 902 and control module 906 which passes frequency parameter 910 to band equalizer 908. The frequency parameter specifies the center frequency of the various bands used in both band pass filter 902 and band equalizer 908. Frequency parameter 910 should be set to the center frequency of the vulnerable frequency band assigned to this particular frequency band limiter stage.

Bandwidth parameter 912 is provided to control module 906 which passes it on to band equalizer 908. The bandwidth parameter specifics the width of the band of frequencies about the center frequency that the equalizer should apply the supplied gain or attenuation.

Limit parameter 914 is provided to control module 906 which specifies the absolute distortion power threshold of the speaker at the vulnerable frequency band. Control module 906 can use the limit parameter along with the master volume parameter to determine the relative distortion power threshold and adjust band equalizer 908 accordingly.

Attack time parameter 916 is an optional parameter which sets the attack time of band equalizer 908. For example, suppose a song is playing with very little power at the vulnerable frequency band and suddenly there is an abrupt crescendo in the music causing the power at the vulnerable frequency band to rise rapidly and suddenly. A sudden high attenuation by band equalizer 908 can cause undesired artifacts to the listener. As a result it may be more desirable to gradually increase the attenuation over the attack period. Furthermore, if a delay line such as shown in FIG. 4 is used, the attenuation can begin prior to the abrupt rise in power at the vulnerable frequency band so that by the time the power reaches the peak, the attenuation has risen to a level sufficient to prevent speaker distortion. Typical attack times range from 50 to 200 milliseconds.

Release time parameter 918 is an optional parameter which sets the release time of band equalizer 908. Just as an abrupt increase in attenuation can have undesired listening effect, so can an abrupt removal of attenuation. The release time is the interval of time for the attenuation to be removed. Typical release times range from 1 to 5 seconds.

Bandwidth bandpass parameter 920 specifies the bandwidth of bandpass filter 902. Essentially, it should be set to cover the vulnerable frequency band monitored by the monitoring module. Generally, the same value is used as bandwidth parameter 914, but there are circumstances that a different value is desired.

Finally, master volume parameter 922 specifies the volume set by the user. The parameter is used to determine the relative distortion power threshold. For example, the relative distortion power threshold is essentially the absolute distortion power threshold minus the master volume. If the power levels detected in the vulnerable frequency band then the attenuation (or gain), expressed in dBs, applied can be set to the distortion power threshold minus measured power levels minus the master volume.

Because any filtering can have an undesired effect on the music played back, the filtering of vulnerable frequency bands can be minimized to occasions when filtering is needed to avoid distortion by the speaker. Other approaches to limiting speaker distortion resort to suppression or filtering of vulnerable frequency bands constantly. The result is that music can sound thin or filtered. Furthermore, filtering performed by the systems and methods disclosed herein may be configured such that suppression of the vulnerable frequency bands during soft passages in music, if any, is small whereas the suppression may be greater during loud passages. Overall, the impact on the playback of music is reduced while maintaining the ability to reduce speaker distortion.

To further minimize the filtering performed, control module 906 can also exploit known psychoacoustic properties. Generally, speaker distortion results in artifacts in certain frequencies. A given vulnerable frequency band when the distortion power threshold is exceeded can produce artifacts in one or more artifact frequencies. In psychoacoustics, certain frequencies are known to mask other frequencies, that is when a masking frequency is present then the frequency that is masked is not perceived by the human ear. If the masking frequencies are present with enough energy to mask the artifact frequencies, then the distortion will not be heard by the human ear and attenuation of the vulnerable frequency band can be avoided in this circumstance.

In many playback systems such as stereophonic, multiple speakers are used as well as multiple channels. While the speaker distortion reduction techniques and systems described above could be used to reduce speaker distortion, not all channels necessarily would reach the distortion power threshold at the same time. If speaker distortion reduction is performed independently on each channel. The playback effect could be altered. For example, the stereo effect could be changed or lost.

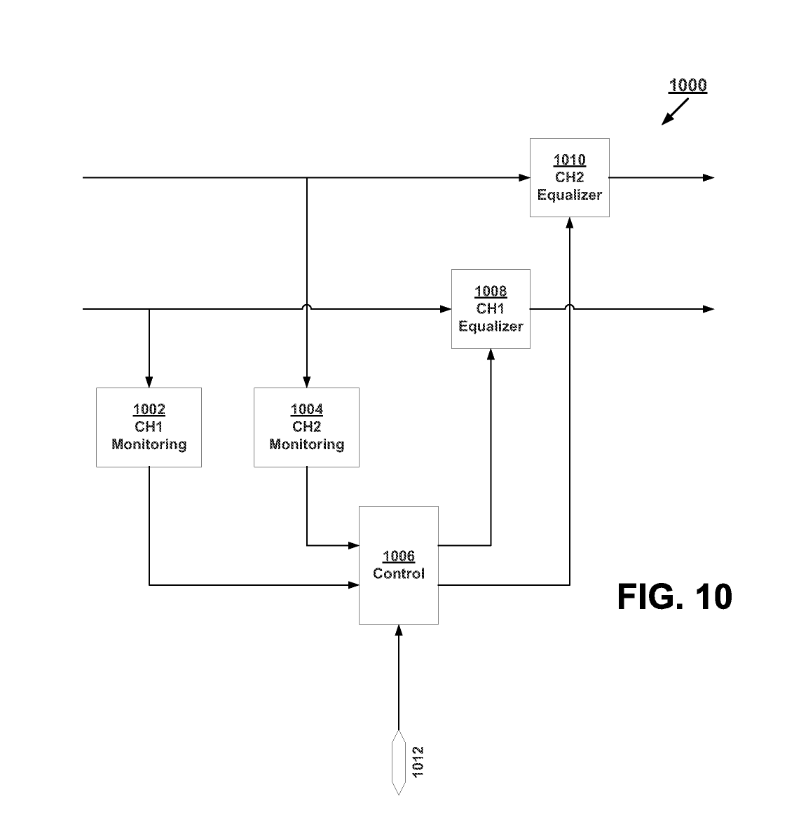

FIG. 10 illustrates an embodiment of a multi-channel audio playback system. In this example, two channels are shown, but the principle could be applied to more channels such as surround sound playback. System 1000 comprises a monitoring module (1002 and 1004) and an equalizer (1008 and 1010) for each channel. Control module 1006 is configurable and operates much as described in the various embodiments described above. However, control module 1006 also receives a channel lock parameter 1012. If the channel lock parameter indicates a channel locking state. Control module 1006 will apply equalization to both channels equally. As a result, effects such as stereo effects will be affected less. In the case of stereo playback, it may be desirable for attenuation be applied to both channels equally. However, there may be circumstances where locking a proportionate attenuation is desired. For example, it may be desirable to attenuate a surround channel less than a center, left or right channel, but a proportional lock may be desired. Additionally, in systems with more than two channels, it may not be desirable to lock all channels, for example, it might be desirable to lock left, center and right channels together, but not a surround channel.

It should be emphasized that the above-described embodiments are merely examples of possible implementations. Many variations and modifications may be made to the above-described embodiments without departing from the principles of the present disclosure. For example, rather than monitor power, any measure of signal intensity can be used, for example the magnitude of the signal itself can be measured and an intensity based threshold can be used instead of the distortion power threshold. All such modifications and variations are intended to be included herein within the scope of this disclosure and protected by the following claims.

What is claimed:

1. A playback system comprising:
an equalizer configured to selectively attenuate a vulnerable frequency band in an input audio signal; and
a control module operable to adjust the attenuation of the equalizer when a signal intensity of the vulnerable frequency band in the input audio signal exceeds a predetermined distortion power threshold associated with the vulnerable frequency band

2. The playback system of claim 1 further comprising a delay line which delays the equalizer module in receiving the input audio signal.

3. The playback system of claim 1 further comprising a monitoring module operable to receive the input audio signal and output to the control module a measure of the signal intensities, the monitoring module comprising:
a band pass filter substantially centered about a center frequency of the vulnerable frequency band and having a width as least as great as a bandwidth of the vulnerable frequency band; and
a root mean square (RMS) module configured to measure the RMS power of the output of the band pass filter.

4. The playback system of claim 1 wherein the equalizer module is substantially centered about a center frequency of the vulnerable frequency band and has a width as great as a bandwidth of the vulnerable frequency band.

5. The playback system of claim 1 wherein the control module adjusts the attenuation of the equalizer on the basis of configuration parameters.

6. The playback system of claim 1 wherein the configuration parameters include at least one of an attack time, a release time and a master volume.

7. The playback system of claim 1 further comprising a speaker configured to receive the attenuated input audio system, wherein the vulnerable frequency band is associated with a low distortion power threshold of the speaker.

8. The playback system of claim 1 wherein the signal intensity is an RMS power.

9. A method of reducing distortion in a speaker comprising:
monitoring power levels of an input audio signal in a vulnerable frequency band of the speaker;
determining whether the power levels exceed a distortion power threshold;
if the power levels exceed the distortion power threshold, attenuating the input audio signal to produce an attenuated audio signal, wherein the attenuated audio signal has power levels in the vulnerable frequency band less than the distortion power threshold.

10. The method of claim 9 further comprising delaying the input audio signal before attenuating the input audio signal.

11. The method of claim 9 wherein the monitoring comprises filtering the input signal with a band pass filter and measuring a power level from the band pass filter.

12. The method of claim 9 wherein the attenuating comprises applying a band equalizer;

13. The method of claim 9 wherein the attenuating is performed on the basis of an attack time parameter.

14. The method of claim 9 wherein the attenuation is performed on the basis of a release time parameter.

15. The method of claim 9 wherein the attenuation is performed on the basis of a master volume parameter.

16. A playback system comprising:
an equalizer configured to selectively attenuate a vulnerable frequency band in an input audio signal to produce an equalized signal; and
a control module operable to adjust the attenuation of the equalizer based on a signal intensity of the vulnerable frequency band in the equalized signal and on configuration parameters.

17. The playback system of claim 16 further comprising a monitoring module operable to receive the equalized signal and output to the control module a measure of the signal intensities, the monitoring module comprising:
a band pass filter substantially centered about a center frequency of the vulnerable frequency band and having a width as least as great as a bandwidth of the vulnerable frequency band; and
a root mean square (RMS) module configured to measure the RMS power of the output of the band pass filter.

18. The playback system of claim 16 wherein the equalizer module is substantially centered about a center frequency of the vulnerable frequency band and has a width as great as a bandwidth of the vulnerable frequency band.

19. The playback system of claim 16 wherein the configuration parameters include an attack time, a release time, and/or a master volume.

20. The playback system of claim 16 wherein the signal intensity is an RMS power.
